(19) United States
(12) Patent Application Publication
(10) Pub. No.: US 2013/0109108 A1
(43) Pub. Date: May 2, 2013

(54) METHOD FOR PRODUCING ZINC OXIDE ON GALLIUM NITRIDE AND APPLICATION THEREOF

(71) Applicants: CHING-FUH LIN, Taipei (TW); Chun-Wei KU, Taipei (TW)

(72) Inventors: CHING-FUH LIN, Taipei (TW); Chun-Wei KU, Taipei (TW)

(73) Assignee: NATIONAL TAIWAN UNIVERSITY, Taipei (TW)

(21) Appl. No.: 13/343,511

(22) Filed: Jan. 4, 2012

(30) Foreign Application Priority Data
Oct. 31, 2011 (TW) 100139671

(51) Int. Cl. H01L 21/30; H01L 21/20

(52) U.S. Cl. 438/4; 438/478; 257/E21.09; 257/E21.211

(57) ABSTRACT

The present invention relates to a method for producing zinc oxide on gallium nitride and application thereof, and particularly relates to a method for producing zinc oxide on gallium nitride by hydrothermal method and a method for recycling substrates by the zinc oxide.

### CROSS-REFERENCE TO RELATED APPLICATIONS

The entire contents of Taiwan Patent Application No. 100139671, filed on Oct. 31, 2011, from which this application claims priority, are incorporated herein by reference.

### BACKGROUND OF THE INVENTION

1. Field of the Invention

The present invention relates to a method for producing zinc oxide on gallium nitride and application thereof, and particularly relates to a method for producing zinc oxide on gallium nitride by hydrothermal method and a method for recycling substrates by the zinc oxide.

2. Description of Related Art

Currently, with the trend of increasing applications of zinc oxide nano structure, zinc oxide epitaxial layer is attempted to be grown on various substrates, for example Si[4], 6H-SiC[5], NiO[6], indium-tin-oxide (ITO)[7], diamond[8], GaN[9-13], etc. Generally, for forming a zinc oxide epitaxial layer on different substrates, a gallium nitride layer is formed as an interlayer between the zinc oxide epitaxial layer and the substrates to enhance the adhesion between the zinc oxide epitaxial layer and different substrates. It is because the crystal structure of gallium nitride is the same with the crystal structure of zinc oxide, the lattice constant of gallium nitride is similar to the lattice constant of zinc oxide and the thermal conductivity of gallium nitride is similar to the thermal conductivity of zinc oxide.

Generally, the zinc oxide thin film (or zinc oxide epitaxial layer) is formed on the gallium nitride layer by electrochemical deposition, pulsed laser deposition, metalorganic chemical vapor deposition, or molecular beam epitaxy. However, the environment and the processing condition of epitaxial growth are critical, for example requirements of high temperature (higher than 100° C.) and metal assistance. Furthermore, cost of these methods is very high. Therefore, there is a need of a method for producing a zinc oxide thin film (or zinc oxide epitaxial layer) on gallium nitride (layer) which has advantages of simple environment and condition of epitaxial growth, simple process (or steps) and low cost.

Additionally, processes of producing optical elements or photoelectric elements, for example light emitting diode (LED), are performed on a substrate and the substrate is discarded after the optical elements (or photoelectric elements) are completed and lifted off from the substrate. Obviously, these methods (or processes) do not accord with environment protection requirements, and these methods (or processes) result in the waste. The producing cost of the optical elements (or photoelectric elements) cannot be decreased because of the waste. Therefore, there is a need of a method for recycling substrates after the optical elements (or photoelectric elements) are completed and for decreasing the producing cost of the optical elements (or photoelectric elements).

### SUMMARY OF THE INVENTION

In view of the foregoing, one object of the present invention is to provide a method for producing zinc oxide on gallium nitride instead of the conventional methods having a need of high cost and critical processing condition, such as electrochemical deposition, pulsed laser deposition, metalorganic chemical vapor deposition, and molecular beam epitaxy. Therefore, the difficulty and the cost for producing the zinc oxide thin film (or zinc oxide epitaxial layer) on gallium nitride (layer).

Another object of the present invention is to provide a method for recycling substrates by the zinc oxide. In this method, the zinc oxide thin film on the substrate is utilized to perform the process for producing the optical elements (or photoelectric elements) and to recycle the substrate to producing the optical elements (or photoelectric elements) repeatedly after the optical elements (or photoelectric elements) are completed. Therefore, the producing cost of the optical elements (or photoelectric elements) can be decreased and the process can be improved to accord with environment protection requirements.

According to the objects above, a method for producing zinc oxide on gallium nitride is disclosed herein. The method comprises following steps: (1) providing a substrate; (2) forming a gallium nitride layer on the substrate; and (3) forming a zinc oxide thin film on the gallium nitride layer by hydrothermal method.

According to the objects above, a method for recycling substrates by the zinc oxide is disclosed herein. The method comprises following steps: (1) providing a substrate; (2) forming a gallium nitride layer on the substrate; (3) forming a zinc oxide thin film on the gallium nitride layer; (4) forming a semiconductor crystal or epitaxial crystal on the zinc oxide thin film for producing an optical element wherein said zinc oxide thin film is used as an epitaxial center; (5) removing the zinc oxide thin film to lift off the semiconductor crystal or epitaxial crystal from the substrate and to recycle the substrate having said gallium nitride layer thereon; and (6) repeating the steps (3)-(5) for producing optical element repeatedly.

Therefore, the present invention provides a method for producing zinc oxide on gallium nitride and this method having advantages of less processing condition requirements, less difficulty and low cost is provided in this invention instead of the conventional method having much processing condition requirements, much difficulty and high cost. Furthermore, this invention provides a method for recycling substrates by the zinc oxide, which is produced by foregoing method. By such method, the substrate which is used in producing process of the optical elements (or photoelectric elements) can be recycled repeatedly and utilized the recycled substrate to produce the optical elements (or photoelectric elements) repeatedly. Therefore, the processing cost of the optical elements (or photoelectric elements) can be decreased.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A to FIG. 1E are a series of cross-section drawings illustrating a method for producing zinc oxide on gallium nitride and application thereof in accordance with an embodiment of the present invention.

### DESCRIPTION OF THE PREFERRED EMBODIMENT

The detailed description of the present invention will be discussed in the following embodiments, which are not intended to limit the scope of the present invention, and can be adapted for other applications. While drawings are illustrated in detail, it is appreciated that the quantity of the disclosed components may be greater or less than that disclosed, except where expressly restricting the amount of the components. Although specific embodiments have been illustrated and described, it will be appreciated by those skilled in the art that various modifications may be made without departing from the scope of the present invention, which is intended to be limited solely by the appended claims.

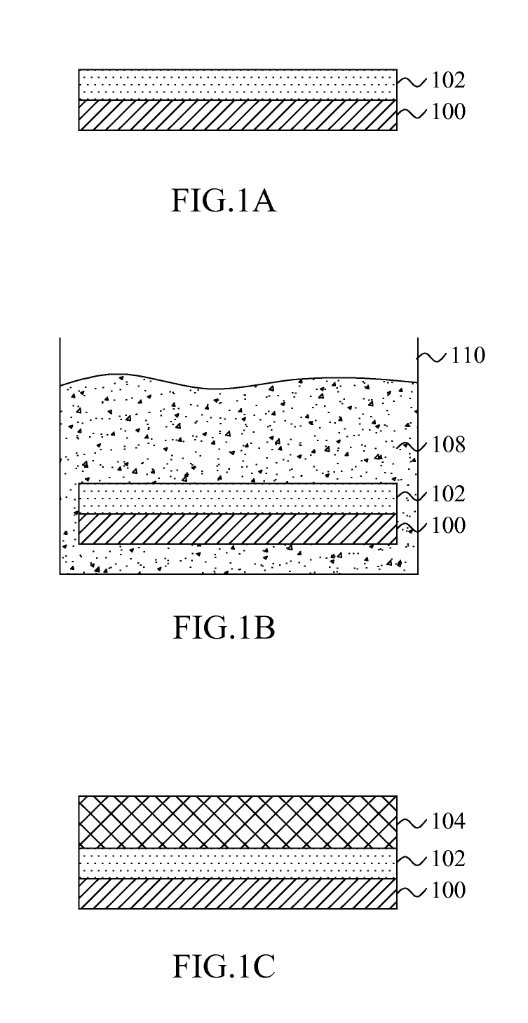

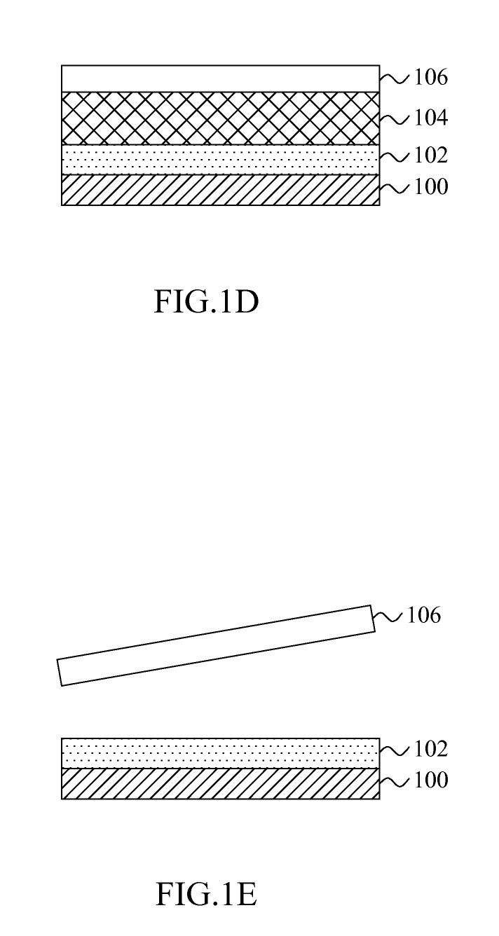

FIG. 1A to FIG. 1D show a method for producing zinc oxide on gallium nitride in accordance with an embodiment of the present invention, and they are a series of cross-section drawings illustrating the process of this method and different steps of this method. Referring to FIG. 1A, first, a substrate 100 is provided wherein substrate 100 is metal, silicon (Si), quartz, glass, sapphire, or polyethylene terephthalate (PET). Then, a gallium nitride layer 102 is formed on the substrate 100. The gallium nitride layer 102 is formed on the substrate 100 by atomic layer deposition, electrochemical deposition, pulsed laser deposition, or metalorganic chemical vapor deposition. According to designs and requirements of the process, the gallium nitride layer can be a non-doped gallium nitride layer, n type gallium nitride layer or p type gallium nitride layer.

After, the substrate 100 and the gallium nitride layer 102 formed thereon are cleared by acetone or methanol, and then, the substrate 100 and the gallium nitride layer 102 are washed by deionized water and are blown for drying. Then, referring to FIG. 1B, the substrate 100 is put into or dipped into a container 110 containing a chemical solution 108 therein for forming a zinc oxide thin film by hydrothermal method. The chemical solution 108 is a zinc nitrate/hexamethylenetetramine aqueous solution or any mixed aqueous solution in which zinc oxide is precipitated through chemical reaction. The concentration of the chemical solution 108 is 50 mM to 220 mM, and different chemical solutions or different concentration of the chemical solution can be adopted to form the zinc oxide thin film according to the requirements of the process, for example required deposition rate. The zinc oxide thin film is formed by hydrothermal method at 60° C. to 90° C. In another embodiment of this invention, the hydrothermal method is performed at 65° C. to 75° C. to form the zinc oxide thin film on the gallium nitride layer 102. The process time of the hydrothermal method is 1 hour to 100 hours, for example 1 hour to 24 hours, and it can be determined according to the process conditions, for example process temperature, and composition and concentration of the chemical solution 108.

Then, referring to FIG. 1C, after zinc oxide is deposited on the gallium nitride layer 102 to form a zinc oxide thin film 104 of a predetermined thickness, the substrate 100 is moved from the container 110 (or the chemical solution 108) and the zinc oxide thin film 104 is completed. The thickness of the zinc oxide thin film 104 (the predetermined thickness) is 0.5 μm to 100 μm, but different thickness of the zinc oxide thin film 104 can be chosen or determined according to requirements of this process or following processes. After the zinc oxide thin film 104 is formed or completed, a following process for producing optical elements (or photoelectric elements) can be performed on the zinc oxide thin film 104. Referring to FIG. 1D, after the zinc oxide thin film 104 is formed or completed, the zinc oxide thin film 104 is used as an epitaxial center to form or grow one layer or multiple layers of nitride semiconductor crystal or nitride epitaxial crystal 106 on the zinc oxide thin film 104 for forming optical elements (or photoelectric elements), for example light emitting diode (LED). The number of the layer of the nitride semiconductor crystal or nitride epitaxial crystal 106 is determined by the kind and the structure of the desired optical elements (or photoelectric elements). The nitride semiconductor crystal or nitride epitaxial crystal 106 is formed by atomic layer deposition, electrochemical deposition, pulsed laser deposition, or metalorganic chemical vapor deposition.

In the method for producing zinc oxide on gallium nitride illustrated in FIG. 1A to FIG. 1D, the zinc oxide thin film is formed in a mixed aqueous solution in which zinc oxide is precipitated through chemical reaction, for example a zinc nitrate/hexamethylenetetramine aqueous solution, at a temperature lower than 100° C. (60° C. to 90° C.) for 1 hour to 100 hours. Therefore, the zinc oxide is formed on gallium by the method with simple process conditions and simple steps as the method illustrated in FIG. 1A to FIG. 1D without the critical process conditions as the conventional method for producing zinc oxide on gallium nitride, for example high temperature (higher than 100° C.) and metal assisting. Furthermore, the process for producing can be simplified and the producing cost of zinc oxide can be decreased because the producing cost of zinc oxide for these critical process conditions is not necessary.

Furthermore, a method for recycling substrates by zinc oxide is provided in this invention, and particularly, a method for recycling substrates by zinc oxide which is formed by above-mentioned method. FIG. 1A to FIG. 1E show a method for recycling substrates by zinc oxide in accordance with an embodiment of the present invention, and are a series of cross-section drawings illustrating the process of this method and different steps of this method.

The above-mentioned steps illustrated in FIG. 1A to FIG. 1D is performed to form the gallium nitride layer 102 on the substrate 100, to form the zinc oxide thin film 104 on the gallium nitride layer 102, and to form one layer or multiple layers of nitride semiconductor crystal or nitride epitaxial crystal 106 on the zinc oxide thin film 104 in order. These steps are not described herein again because the steps are the same as the above-mentioned method for producing zinc oxide on gallium nitride. However, it is noticed that although in the method for recycling substrates by zinc oxide illustrated in FIG. 1A to FIG. 1E, the hydrothermal method having advantages of simple process steps, less process conditions (or requirements) and low process (or producing) cost is the best method for forming the zinc oxide thin film 104 on the gallium nitride layer 102, but other methods having disadvantages of complicated process steps, much process conditions (or requirements) and critical process (or producing) cost, such as thermal evaporation, chemical vapor deposition, molecular beam epitaxy, or anodic aluminum oxide (AAO), still can be utilized to form the zinc oxide thin film 104 on the gallium nitride layer 102 according to the requirements of the process. Therefore, the method for producing the zinc oxide thin film 104 on the gallium nitride layer 102 is not limited to the hydrothermal method.

Then, referring to FIG. 1E, after the nitride semiconductor crystal or nitride epitaxial crystal 106 is formed on the zinc oxide thin film 104 to construct the optical element(s) (or photoelectric element(s)), the zinc oxide thin film 104 is etched by an acid solution for removing the zinc oxide thin film 104. Therefore, the nitride semiconductor crystal or nitride epitaxial crystal 106 on the zinc oxide thin film 104 is separated from the substrate 100 or the gallium nitride layer 102, and it is lifted off from the substrate 100 or the gallium nitride layer 102. In other words, the zinc oxide thin film 104 is completely etched for lifting off the optical element(s) (or photoelectric element(s)) constructed on the zinc oxide thin film 104 from the substrate 100 (or the gallium nitride layer 102). The acid solution is a hydrochloric acid, acetic acid, sulfuric acid, nitric acid, or mixed solution of two or more of these acids. Different concentrations of the acid solution can be determined or chosen to etch the zinc oxide thin film 104 according to the requirements of the process, for example the concentrations of the acid solution is determined or chosen according to the desired etching rate or etching time.

Finally, the substrate 100 is recycled to produce the optical element(s) (or photoelectric element(s)) again. At this time, only the steps illustrated in FIG. 1B to FIG. 1E are repeated or performed to form the zinc oxide thin film 104 on the gallium nitride layer 102, and to form one layer or multiple layers of nitride semiconductor crystal or nitride epitaxial crystal 106 on the zinc oxide thin film 104, to remove the zinc oxide thin film 104, and to recycle the substrate 100 for producing the optical element(s) (or photoelectric element(s)) until the substrate 100 cannot be used further because the gallium nitride layer 102 has been formed on the substrate 100 previously. Therefore, before the substrate is worn, broken or damaged to certain extent that the substrate cannot be used anymore, the substrate can be repeatedly recycled to be used in production of the optical element(s) (or photoelectric element(s)). It helps to reduce the producing (or process) cost significantly and it accords with environment protection requirements because the substrate is not discarded as conventional methods after the substrate is used to produce the optical element(s) (or photoelectric element(s)) once.

Accordingly, a method for producing zinc oxide on gallium nitride is provided in this invention, in which the hydrothermal method having advantages of simple process steps, less process conditions (or requirements) and low process (or producing) cost is utilized instead of the conventional methods having disadvantages of complicated process steps, much process conditions (or requirements) and critical process (or producing) cost, such as thermal evaporation, chemical vapor deposition, molecular beam epitaxy, or anodic aluminum oxide (AAO), to produce the zinc oxide thin film on the gallium nitride layer. By this way, the difficulty and cost of production of the optical element(s) (or photoelectric element(s)) can be reduced or decreased. Thus, the process of production of the optical element(s) (or photoelectric element(s)) is simplified and the requirements (or conditions) and cost of production of the optical element(s) (or photoelectric element(s)) are decreased. Furthermore, a method for recycling substrates by applying the method of this invention to produce zinc oxide on gallium nitride is provided in this invention. The substrate can be recycled repeatedly to produce the optical element(s) (or photoelectric element(s)). Therefore, the process (or producing) cost of optical element(s) (or photoelectric element(s)) can be significantly decreased by the recycling method of this invention.

What is claimed is:

1. A method for producing zinc oxide on gallium nitride by hydrothermal method, comprising:
(1) providing a substrate;
(2) forming a gallium nitride layer on said substrate; and
(3) forming a zinc oxide thin film on said gallium nitride layer by hydrothermal method.

2. The method of claim 1, wherein further comprising a step of forming an optical element on said zinc oxide thin film, and said zinc oxide thin film is used to be an epitaxial center for forming a semiconductor crystal or epitaxial crystal.

3. The method of claim 1, wherein said substrate is metal, silicon (Si), quartz, glass, sapphire, or polyethylene terephthalate (PET).

4. The method of claim 1, wherein said gallium nitride layer is a non-doped gallium nitride layer, n type gallium nitride layer or p type gallium nitride layer.

5. The method of claim 1, wherein said step (2) is performed by atomic layer deposition, electrochemical deposition, pulsed laser deposition, or metalorganic chemical vapor deposition.

6. The method of claim 1, wherein in said step (3), a zinc nitrate/hexamethylenetetramine aqueous solution or a mixed aqueous solution, in which zinc oxide is precipitated through chemical reaction, is used as a chemical solution for forming said zinc oxide thin film on said gallium nitride layer.

7. The method of claim 6, wherein concentration of said chemical solution is 50 mM to 220 mM.

8. The method of claim 1, wherein said step (3) is performed at 60° C. to 90° C.

9. The method of claim 1, wherein process time of said step (3) is 1 hour to 100 hours.

10. The method of claim 1, wherein thickness of said zinc oxide thin film is 0.5 μm to 100 μm.

11. The method of claim 1, wherein further comprising:
clearing said substrate having said gallium nitride layer formed thereon by acetone or methanol; and
washing said substrate by deionized water and drying said substrate.

12. A method for recycling substrates by zinc oxide, comprising:
(1) providing a substrate;
(2) forming a gallium nitride layer on said substrate;
(3) forming a zinc oxide thin film on said gallium nitride layer;
(4) forming a semiconductor crystal or epitaxial crystal on said zinc oxide thin film for producing an optical element wherein said zinc oxide thin film is used as an epitaxial center;
(5) removing said zinc oxide thin film to lift off said semiconductor crystal or epitaxial crystal from said substrate and to recycle said substrate having said gallium nitride layer thereon; and
(6) repeating said steps (3)-(5) for producing optical element repeatedly.

13. The method of claim 12, wherein said substrate is metal, silicon (Si), quartz, glass, sapphire, or polyethylene terephthalate (PET).

14. The method of claim 12, wherein said gallium nitride layer is a non-doped gallium nitride layer, n type gallium nitride layer or p type gallium nitride layer.

15. The method of claim 12, wherein said step (2) is performed by atomic layer deposition, electrochemical deposition, pulsed laser deposition, or metalorganic chemical vapor deposition.

16. The method of claim 12, wherein further comprising a clearing step performed before said step (3), said clearing step comprises:
clearing said substrate having said gallium nitride layer formed thereon by acetone or methanol; and
washing said substrate by deionized water and drying said substrate.

17. The method of claim 12, wherein said step (3) is performed by hydrothermal method, thermal evaporation, chemical vapor deposition, molecular beam epitaxy, or anodic aluminum oxide (AAO).

18. The method of claim 12, wherein in said step (3), a zinc nitrate/hexamethylenetetramine aqueous solution or a mixed aqueous solution, in which zinc oxide is precipitated through chemical reaction, is used as a chemical solution of hydrothermal method for forming said zinc oxide thin film on said gallium nitride layer by said hydrothermal method.

19. The method of claim 18, wherein concentration of said chemical solution is 50 mM to 220 mM.

20. The method of claim 18, wherein said step (3) is performed at 60° C. to 90° C.

21. The method of claim 18, wherein process time of said step (3) is 1 hour to 100 hours.

22. The method of claim 12, wherein thickness of said zinc oxide thin film is 0.5 μm to 100 μm.

23. The method of claim 12, wherein said step (4) is performed by atomic layer deposition, electrochemical deposition, pulsed laser deposition, or metalorganic chemical vapor deposition.

24. The method of claim 12, wherein said step (5) is performed by etching said zinc oxide thin film with an acid solution.

25. The method of claim 24, wherein said acid solution is a hydrochloric acid, acetic acid, sulfuric acid, nitric acid, or mixed solution of said acids.
